(19) United States
(12) Patent Application Publication
(10) Pub. No.: US 2017/0236964 A1
(43) Pub. Date: Aug. 17, 2017

(54) SOLAR CELL MODULE

(71) Applicant: KYOCERA CORPORATION, Kyoto (JP)

(72) Inventors: Takahiro ARIMA, Yasu-shi (JP); Takemichi HONMA, Hikone-shi (JP); Kitae HIRAYAMA, Otsu-shi (JP)

(21) Appl. No.: 15/499,667

(22) Filed: Apr. 27, 2017

Related U.S. Application Data
(63) Continuation of application No. PCT/JP2015/080559, filed on Oct. 29, 2015.

(30) Foreign Application Priority Data
Oct. 29, 2014 (JP) 2014-220529

(51) Int. Cl. H01L 31/05; H01L 31/02; H01L 31/0224

(52) U.S. Cl. CPC H01L 31/0508; H01L 31/022441; H01L 31/0201

(57) ABSTRACT

A solar cell module comprises a solar cell element, first and second connection tabs, and first and second solder portions. The solar cell element includes a semiconductor substrate, a front busbar electrode, and a back busbar electrode. The first solder portion connects the front busbar electrode and the first connection tab. The second solder portion connects the back busbar electrode and the second connection tab. A distance between the first lateral surface and a first bonding surface where the first solder portion is bonded to the front busbar electrode is shorter than a distance between the first lateral surface and a second bonding surface where the second solder portion is bonded to the back busbar electrode. A distance between the second lateral surface and the first bonding surface is shorter than a distance between the second lateral surface and the second bonding surface.

### CROSS-REFERENCE TO RELATED APPLICATION

The present application is a continuation based on PCT Application No. PCT/JP2015/080559 filed on Oct. 29, 2015, which claims the benefit of Japanese Application No. 2014-220529, filed on Oct. 29, 2014. PCT Application No. PCT/JP2015/080559 is entitled “SOLAR CELL MODULE”, and Japanese Application No. 2014-220529 is entitled “SOLAR CELL MODULE”. The contents of which are incorporated by reference herein in their entirety.

### FIELD

Embodiments of the present disclosure relate generally to solar cell modules.

### BACKGROUND

For example, a solar cell module that includes a connection tab soldered to each of a front busbar electrode and a back busbar electrode of a solar cell element has been known.

### SUMMARY

A solar cell module is disclosed. In one embodiment, a solar cell module comprises a solar cell element, a first connection tab, a first solder portion, a second connection tab, and a second solder portion. The solar cell element includes a semiconductor substrate, a front busbar electrode, and a back busbar electrode. The semiconductor substrate has a first lateral surface and a second lateral surface located opposite to the first lateral surface. The front busbar electrode is located on a first surface side of the semiconductor substrate along a direction from the first lateral surface toward the second lateral surface. The back busbar electrode is located on a second surface side opposite to the first surface side of the semiconductor substrate along the direction from the first lateral surface toward the second lateral surface so as to be located at a position opposite to the front busbar electrode with the substrate interposed therebetween. The first connection tab is located just above the front busbar electrode along a longitudinal direction of the front busbar electrode and includes one end portion located on the first lateral surface side of the semiconductor substrate. The first solder portion is located between the front busbar electrode and the first connection tab and connects the front busbar electrode and the first connection tab to each other. The second connection tab is located just above the back busbar electrode along a longitudinal direction of the back busbar electrode and includes one end portion located on the second lateral surface side of the semiconductor substrate. The second solder portion is located between the back busbar electrode and the second connection tab and connects the back busbar electrode and the second connection tab to each other. A shortest distance between the first lateral surface and a first bonding surface where the first solder portion is bonded to the front busbar electrode is shorter than a shortest distance between the first lateral surface and a second bonding surface where the second solder portion is bonded to the back busbar electrode. A shortest distance between the second lateral surface and the first bonding surface is shorter than a shortest distance between the second lateral surface and the second bonding surface.

### BRIEF DESCRIPTION OF THE DRAWINGS

FIG. 1 illustrates a plan view showing one example of an external appearance on a first surface side of a solar cell element included in a solar cell module according to one embodiment.

FIG. 2 illustrates a plan view showing one example of an external appearance on a second surface side of the solar cell element included in the solar cell module according to one embodiment.

FIG. 3 illustrates a cross-sectional view showing an example of a cross section of the solar cell element taken along an III-III line in FIG. 1.

FIGS. 4A to 4D each illustrate an example of a planar shape of a front busbar electrode of the solar cell element included in the solar cell module according to one embodiment. FIGS. 4A to 4D each illustrate only an enlarged portion of one end portion side of the front busbar electrode.

FIG. 5 illustrates a plan view showing one example of an external appearance of the solar cell module according to one embodiment.

FIG. 6 illustrates an enlarged cross-sectional view showing an enlarged portion of a cross section of the solar cell module taken along a VI-VI line in FIG. 5.

FIG. 7 illustrates an enlarged cross-sectional view showing an enlarged VII portion in FIG. 6.

FIG. 8 illustrates an enlarged cross-sectional view showing an enlarged VIII portion in FIG. 6.

FIG. 9A illustrates a plan view showing an enlarged IXa portion in FIG. 5. FIG. 9B illustrates a cross-sectional view showing a portion of a cross section of the solar cell module taken along an IXb-IXb line in FIG. 9A.

### DETAILED DESCRIPTION

Some solar cell modules, for example, include a connection tab soldered to each of a front busbar electrode and a back busbar electrode of a solar cell element.

When the connection tab is soldered to each of the electrodes, a temperature of the solar cell element is higher than the melting temperature of solder. A decrease in the temperature of the solar cell element from this state to ambient temperature causes stress in the solar cell element due to contraction of the connection tab. The stress may cause a crack in a semiconductor substrate.

A non-lead solder that does not substantially contain lead may be used as the solder. In this case, the crack is more likely to occur in the semiconductor substrate because the melting point of the non-lead solder is normally higher than that of the solder that contains lead.

Thus, there is room for improvement in the solar cell module to make the crack less likely to occur in the semiconductor substrate of the solar cell element.

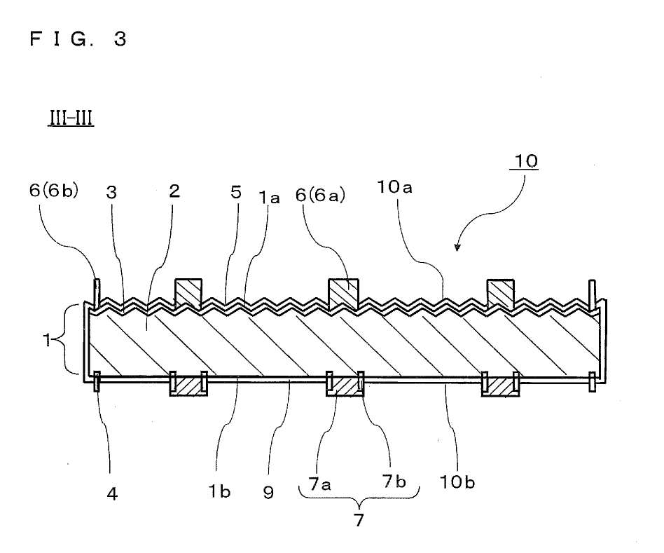

One embodiment and various modifications will be described below with reference to the drawings. The drawings are schematically shown. In addition, part of structural components and hatching are omitted from FIG. 3.

<Solar Cell Element>

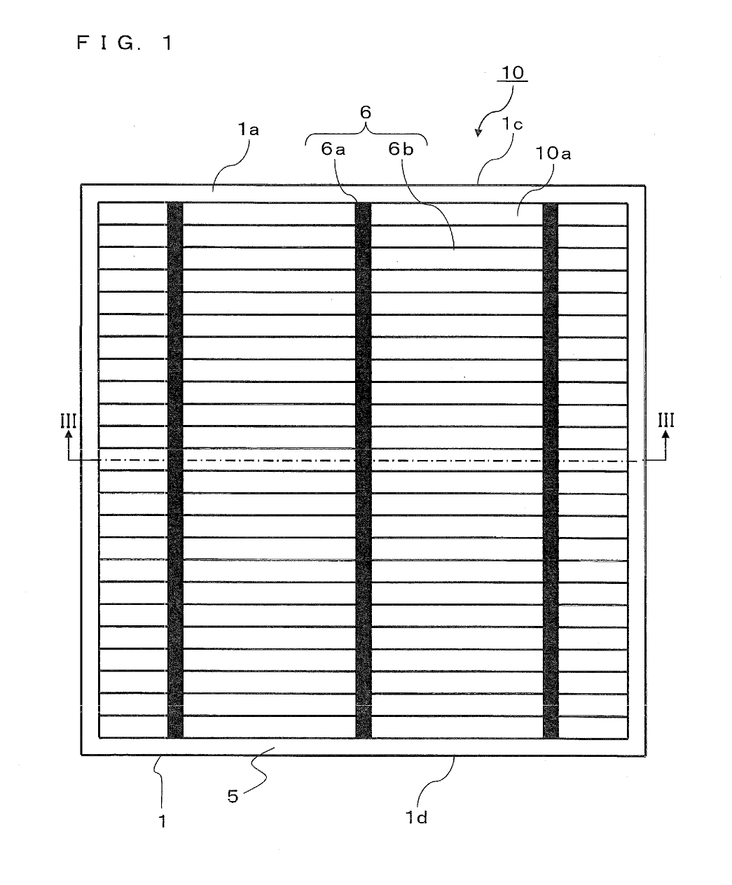

FIGS. 1 to 3 illustrate a solar cell element 10 used in a solar cell module 20 in one embodiment. The solar cell element 10 has a first surface 10a that is a surface (also referred to as a front surface) on which light is mainly incident and a second surface 10b that is a surface (also referred to as a back surface) located opposite to the first surface 10a.

The solar cell element 10 includes a substrate 1 made of silicon being semiconductor. The substrate 1 also has a first surface 1a and a second surface 1b located opposite to the first surface 1a. The substrate 1 further has a first lateral surface 1c and a second lateral surface 1d that connect the first surface 1a and the second surface 1b to each other. Herein, the second lateral surface 1d is located opposite to the first lateral surface 1c.

As illustrated in FIG. 3, the substrate 1 includes a first semiconductor layer 2 that is a semiconductor region of one conductivity type (such as a p-type) and a second semiconductor layer 3 that is a semiconductor region of a reverse conductivity type (such as an n-type) located on the first surface 1a side of the first semiconductor layer 2. Any material other than silicon can be used for the substrate 1 as long as the substrate 1 is the semiconductor substrate that includes the first semiconductor layer 2 and the second semiconductor layer 3.

An example in which a p-type semiconductor is used for the first semiconductor layer 2 is described below. In the case in which the p-type semiconductor is used for the first semiconductor layer 2, a polycrystalline or monocrystalline silicon substrate of the p-type can be used for the substrate 1. For example, a substrate having a thickness of less than or equal to 250 μm may be adopted as the substrate 1, and, furthermore, a thin substrate having a thickness of less than or equal to 150 μm may be adopted as the substrate 1. The substrate 1 can have any planar shape, and the planar shape of the substrate 1 is rectangular in one embodiment to reduce a gap between adjacent solar cell elements. For the first semiconductor layer 2 of the p-type in the polycrystalline silicon substrate, impurities such as boron and/or gallium are contained as dopants in the first semiconductor layer 2.

The second semiconductor layer 3 is located on the first semiconductor layer 2. Thus, a p-n junction is located at an interface between the first semiconductor layer 2 and the second semiconductor layer 3. The second semiconductor layer 3 has the conductivity type (n-type in one embodiment) reverse to that of the first semiconductor layer 2 and is located on the first surface 1a side of the first semiconductor layer 2. The second semiconductor layer 3 may be formed by diffusing impurities such as phosphorus as dopants in a surface layer portion on the first surface 1a side of the substrate 1.

As illustrated in FIG. 3, the solar cell element 10 includes a third semiconductor layer 4, an antireflection layer 5, a front electrode 6, a back electrode 7, and a passivation layer 9 in addition to the substrate 1.

A finely uneven structure (texture) for reducing reflectivity of emitted light may be provided on the first surface 1a side of the substrate 1. In this case, a protruding portion of the texture may have a height of about 0.1 μm to 10 μm, and a distance between peaks of adjacent protruding portions may be about 0.1 μm to 20 μm. The texture may have, for example, a hemispherical depressed portion or a pyramidal protruding portion. The “height of the protruding portion” described above refers to a distance from a reference line, which is a straight line through bottom surfaces of the depressed portions in, for example, FIG. 3, to the peak of the protruding portion in a direction perpendicular to the reference line.

The antireflection layer 5 has the function of reducing the reflectivity of light emitted to the first surface 10a of the solar cell element 10. For example, a silicon oxide layer, an aluminum oxide layer, or a silicon nitride layer is adopted as a material for the antireflection layer 5. The antireflection layer 5 has a refractive index and a thickness to the extent to which conditions of low reflection can be achieved for incident light in a range of wavelengths that may be absorbed by the substrate 1 to contribute to electric power generation. For example, the antireflection layer 5 can have the refractive index of about 1.8 to 2.5 and the thickness of about 20 nm to 120 nm.

The third semiconductor layer 4 is located on the second surface 1b side of the substrate 1. The third semiconductor layer 4 has the same conductivity type (p-type in one embodiment) as that of the first semiconductor layer 2. Note that the third semiconductor layer 4 contains the dopants at a concentration higher than a concentration of the dopants contained in the first semiconductor layer 2. In other words, the third semiconductor layer 4 contains the dopant elements at the concentration higher than that of the dopant elements in the first semiconductor layer 2 to make the third semiconductor layer 4 of the one conductivity type. The third semiconductor layer 4 forms an internal electric field in a portion on the second surface 1b side of the substrate 1. This can make recombination of minority carriers less likely to occur near the second surface 1b of the substrate 1. As a result, a decrease in photoelectric conversion efficiency of the solar cell element 10 can be less likely to occur. The third semiconductor layer 4 may be formed by, for example, diffusing the dopant elements such as boron or aluminum into a surface layer portion on the second surface 1b side of the substrate 1. The first semiconductor layer 2 can contain the dopant elements at the concentration of about 5×10¹⁵ atoms/cm³ to 1×10¹⁷ atoms/cm³ while the third semiconductor layer 4 can contain the dopant elements at the concentration of about 1×10¹⁸ atoms/cm³ to 5×10²¹ atoms/cm³. The third semiconductor layer 4 is located in a contact portion with the back electrode 7 described below and the substrate 1.

The front electrode 6 is located on the first surface 1a side of the substrate 1. As illustrated in FIG. 1, the front electrode 6 includes a front busbar electrode 6a and a plurality of front finger electrodes 6b having a linear shape. The front busbar electrode 6a is used to take electricity obtained from the electric power generation in the substrate 1 out of the solar cell element 10. The front busbar electrode 6a is located on the first surface 1a so as to extend along a direction from the first lateral surface 1c toward the second lateral surface 1d of the substrate 1. The front busbar electrode 6a has a length (hereinafter also referred to as a width) of about 13 mm to 2.5 mm in a direction (also referred to as a lateral direction) orthogonal to a longitudinal direction of the front busbar electrode 6a. At least part of the front busbar electrode 6a is electrically connected to the front finger electrode 6b by intersecting the front finger electrode 6b.

The plurality of front finger electrodes 6b are used to collect the electricity obtained from the electric power generation in the substrate 1 from the substrate 1. Each of the front finger electrodes 6b has a width of, for example, about 50 μm to 200 μm. In this manner, the front finger electrode 6b has the width smaller than the width of the front busbar electrode 6a. The plurality of front finger electrodes 6b are located at an interval of, for example, about 1 mm to 3 mm therebetween. The front electrode 6 has a thickness of, for example, about 10 μm to 40 μm. The front electrode 6 may be formed by, for example, applying a metal paste (also referred to as a first metal paste) that contains silver as a main component into a desired shape by screen printing and then firing the first metal paste. Hereinafter, the “main component” refers to a component that accounts for greater than or equal to 50% of the entire components.

The back electrode 7 is located on the second surface 1b side of the substrate 1. The back electrode 7 includes, for example, a back busbar electrode 7a and a plurality of back finger electrodes 7b. The back busbar electrode 7a is used to take electricity obtained from the electric power generation in the solar cell element 10 out of the solar cell element 10. The back busbar electrode 7a is located on the second surface 1b so as to extend along the direction from the first lateral surface 1c toward the second lateral surface 1d of the substrate 1. The back busbar electrode 7a has a thickness of, for example, about 10 μm to 30 μm. The back busbar electrode 7a has a width of, for example, about 1.3 mm to 7 mm. The back busbar electrode 7a contains, for example, silver as the main component. The back busbar electrode 7a may be formed by, for example, applying a metal paste (also referred to as a second metal paste) that contains silver as the main component into a desired shape by screen printing and then firing the second metal paste.

The plurality of back finger electrodes 7b on the second surface 1b of the substrate 1 are used to collect the electricity obtained from the electric power generation in the substrate 1 from the substrate 1. Each of the back finger electrodes 7b is located so as to be electrically connected to the back busbar electrode 7a. Herein, at least part of the back busbar electrode 7a is electrically connected to the back finger electrode 7b. Each of the back finger electrodes 7b has a thickness of, for example, about 15 μm to 50 μm. Each of the back finger electrodes 7b has a width of, for example, about 100 μm to 500 μm. The plurality of back finger electrodes 7b are located at an interval of, for example, about 1 mm to 3 mm therebetween. Herein, for example, if the back finger electrode 7b has a width larger than a width of the front finger electrode 6b of the front electrode 6 to reduce a series resistance of the back finger electrode 7b, output characteristics of the solar cell element 10 may be improved. The back finger electrode 7b contains, for example, aluminum as the main component. The back finger electrode 7b may be formed by, for example, applying a metal paste (also referred to as a third metal paste) that contains aluminum as the main component into a desired shape by screen printing and then firing the third metal paste.

As described above, the front busbar electrode 6a is located on the first surface 1a of the substrate 1 along the direction from the first lateral surface 1c toward the second lateral surface 1d in the solar cell element 10 in one embodiment. The back busbar electrode 7a is located on the second surface 1b of the substrate 1 along the direction from the first lateral surface 1c toward the second lateral surface 1d so as to be located at a position opposite to the front busbar electrode 6a with the substrate 1 interposed therebetween.

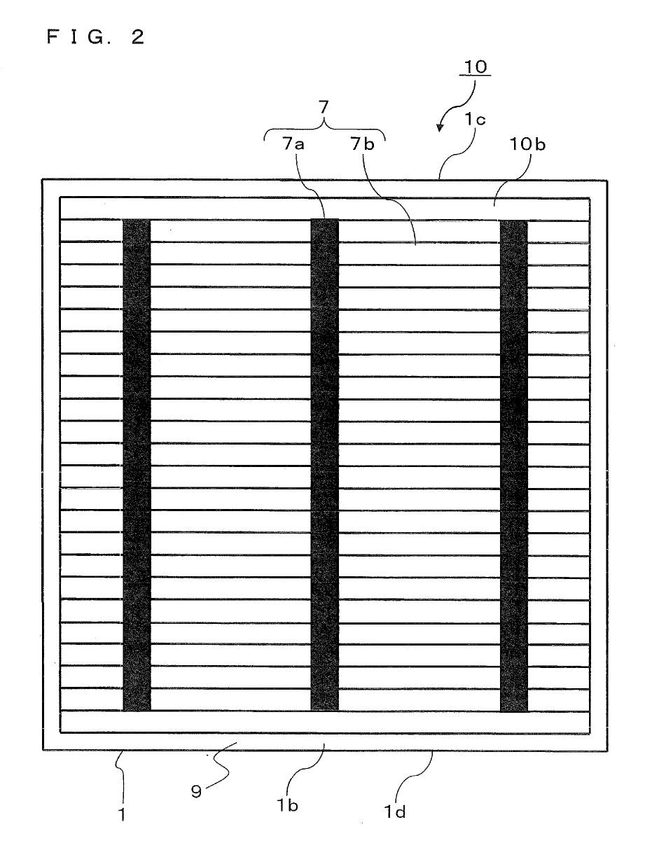

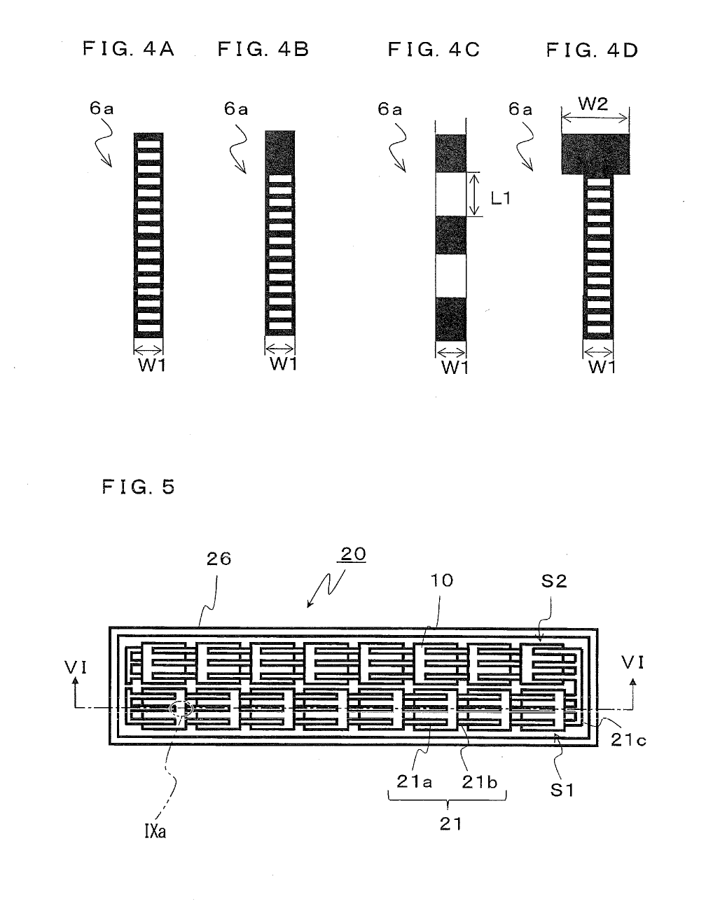

The planar shapes of the front busbar electrode 6a and the back busbar electrode 7a are not limited to the shape of the belt as respectively illustrated in FIGS. 1 and 2, and may be a shape of a ladder or a lattice having a frame-shaped portion with cavities (such as slits), or may be, for example, a shape having a plurality of island-shaped portions that are discontinuous portions. Specifically, the front busbar electrode 6a may have, for example, the frame-shaped portion as illustrated in FIGS. 4A, 4B, and 4D, or may have, for example, the plurality of discontinuous island-shaped portions as illustrated in FIG. 4C. Herein, for example, with regard to the front busbar electrode 6a having the plurality of island-shaped portions as illustrated in FIG. 4C, an electrode including the plurality of island-shaped portions aligned in one row is regarded as one long front busbar electrode 6a. With regard to the back busbar electrode 7a including the plurality of island-shaped portions, an electrode having the plurality of island-shaped portions aligned in one row is regarded as one long back busbar electrode 7a similarly to the front busbar electrode 6a. A distance L1 between the island-shaped portions adjacent to each other can be appropriately determined depending on the number and locations of solder bonding portions (hereinafter also referred to as solder portions 25) of a connection tab 21, which will be described below. To make a width of one end portion of the front busbar electrode 6a wide as illustrated in FIG. 4D, a width W2 of the wide portion may be appropriately determined depending on dimensions of the solder portions 25, which will be described below.

The first surface 10a of the solar cell element 10 is a surface that mainly receives light. Thus, degradation in characteristics of the solar cell element 10 due to light shielding needs to be minimized. Accordingly, for example, the front electrode 6 has an area smaller than an area of the back electrode 7 in a plan view. In addition, for example, the front busbar electrode 6a may have a width smaller than a width of the back busbar electrode 7a.

The passivation layer 9 is located on the second surface 1b of the substrate 1 and has the function of reducing recombination of the minority carriers. The passivation layer 9 is formed of, for example, a layer of one kind or a laminated layer of layers of two or more kinds among silicon oxide, aluminum oxide, silicon nitride, and the like. For example, a layer of aluminum oxide that can be formed by atomic layer deposition (ALD) is adopted as the passivation layer 9. The passivation layer 9 may have a thickness of, for example, about 10 nm to 200 nm. In one embodiment, the passivation layer 9 is located on at least the second surface 1b of the substrate 1, for example, but may be located on both surfaces of the first surface 1a and the second surface 1b. This may improve the passivation performance. If the antireflection layer 5 and the passivation layer 9 are also located on the lateral surfaces of the substrate 1, the characteristics of the solar cell element 10 can be further improved.

One embodiment described above illustrates the case in which the back finger electrode 7b is the linear electrode. However, the back finger electrode 7b may be, for example, an electrode located substantially on the entire surface of the second surface 1b of the substrate 1 except for part of the region where the back busbar electrode 7a is located. In this case, there may be no passivation layer 9, for example. In the presence of the passivation layer 9, a passivated emitter and rear cell (PERC) structure may be adopted, for example.

<Method for Manufacturing Solar Cell Element>

Next, each step of a method for manufacturing the solar cell element 10 is described in detail.

The substrate 1 is formed by, for example, the Czochralski (CZ) process casting or the like. An example in which the polycrystalline silicon substrate of the p-type is used as the substrate 1 is described below.

First, an ingot of polycrystalline silicon is manufactured by, for example, casting. Next, the ingot is processed into a block having appropriate shape and dimensions. The block is cut into slices to manufacture the substrate 1 having a thickness of, for example, less than or equal to 250 μm. Then, the surface of the substrate 1 may be extremely slightly etched with an aqueous solution of sodium hydroxide (NaOH), potassium hydroxide (KOH), or hydrofluoric-nitric acid to clean a mechanically damaged layer and a polluted layer of a cut surface of the substrate 1, for example.

Next, the texture is formed on the first surface 1a of the substrate 1. The texture may be formed by wet etching with an alkaline solution such as NaOH or with an acid solution such as hydrofluoric-nitric acid, or dry etching with the use of reactive ion etching (RIE) or the like.

Then, a step of forming the second semiconductor layer 3 that is the n-type semiconductor region on the first surface 1a of the substrate 1 having the texture formed in the above-mentioned step is performed. Specifically, the second semiconductor layer 3 of the n-type is formed in the surface layer portion on the first surface 1a side of the substrate 1 having the texture.

The second semiconductor layer 3 is formed by, for example, an coating thermal diffusion method in which diphosphorus pentaoxide (P₂O₅) in paste form is applied to the surface of the substrate 1 and phosphorus is thermally diffused, a vapor thermal diffusion in which phosphorus oxychloride (POCl₃) in gaseous form is a source of diffusion of phosphorus, or the like. The second semiconductor layer 3 is formed so as to have, for example, a depth of about 0.1 μm to 2 μm and a sheet resistance of about 40 Ω/□ to 200 Ω/□. For the adoption of the vapor thermal diffusion, for example, heat treatment is performed on the substrate 1 for about 5 minutes to 30 minutes at temperatures between about 600° C. and 800° C. in an atmosphere of diffusion gas that contains POCl₃ and the like. Consequently, a phosphorus glass is formed on the surface of the substrate 1. Then, heat treatment is performed on the substrate 1 for about 10 minutes to 40 minutes at temperatures between about 800° C. and 900° C. in an atmosphere of an inert gas such as argon and nitrogen. As a result, phosphorus is diffused from the phosphorus glass into the substrate 1, and the second semiconductor layer 3 is formed on the first surface 1a side of the substrate 1.

Next, if the second semiconductor layer 3 is also formed on the second surface 1b side of the substrate 1 in the step of forming the second semiconductor layer 3, the second semiconductor layer 3 formed on the second surface 1b side is removed by etching. Consequently, the p-type semiconductor region is exposed from the second surface 1b side of the substrate 1. Herein, for example, only the second surface 1b side of the substrate 1 is immersed in the hydrofluoric-nitric acid solution to remove the second semiconductor layer 3 formed on the second surface 1b side. Subsequently, the phosphorus glass that is formed on the first surface 1a side of the substrate 1 when the second semiconductor layer 3 is formed is removed by etching. In this manner, when the second semiconductor layer 3 formed on the second surface 1b side is removed by etching with the phosphorus glass remaining on the first surface 1a side of the substrate 1, the second semiconductor layer 3 on the first surface 1a side of the substrate 1 is not removed and can thus avoid being damaged. At this time, the second semiconductor layer 3 formed on the lateral surfaces of the substrate 1 may also be removed.

In the step of forming the second semiconductor layer 3 described above, a diffusion mask may be previously formed on the second surface 1b side and removed after the second semiconductor layer 3 is formed by the vapor thermal diffusion. Such a process does not form the second semiconductor layer 3 on the second surface 1b side. Thus, the step of removing the second semiconductor layer 3 on the second surface 1b side is not needed.

As described above, the substrate 1 that includes the second semiconductor layer 3, which is the n-type semiconductor layer, located on the first surface 1a side, and also has the texture on its surface and includes the first semiconductor layer 2 can be prepared.

Next, the passivation layer 9 made of, for example, aluminum oxide is formed on the second surface 1b of the first semiconductor layer 2. The passivation layer 9 can be formed by, for example, ALD or plasma enhanced chemical vapor deposition (PECVD). At this time, the passivation layer 9 may be formed on the entire periphery of the substrate 1 that includes the first surface 1a of the first semiconductor layer 2 and the lateral surfaces of the substrate 1.

In the step of forming the passivation layer 9 by ALD, first, the substrate 1 in which the second semiconductor layer 3 is formed is placed in a chamber of a deposition device. While the substrate 1 is heated to a temperature between about 100° C. and 250° C., (Step 1) to (Step 4) shown below are repeated for multiple times, and thus the passivation layer 9 made of aluminum oxide can be formed.

(Step 1) Supply of an aluminum raw material

(Step 2) Removal of the aluminum raw material by exhaust air

(Step 3) Supply of an oxidizing agent

(Step 4) Removal of the oxidizing agent by exhaust air

Herein, for example, trimethyl aluminum (TMA), triethyl aluminum (TEA) or the like can be used as the aluminum raw material. For example, water, ozone gas or the like can be used as the oxidizing agent.

A film made of silicon nitride and/or silicon oxide may be further formed on aluminum oxide formed on the second surface 1b of the substrate 1 by, for example, PECVD. This can thus form the passivation layer 9 having the function of interface passivation achieved by aluminum oxide and the function as a protective film achieved by silicon nitride and/or silicon oxide.

Next, the antireflection layer 5 made of silicon nitride and the like is formed on the second semiconductor layer 3 on the first surface 1a side of the substrate 1. The antireflection layer 5 can be formed by, for example, PECVD or sputtering. For PECVD, the substrate 1 is preheated at a temperature higher than a temperature during deposition. Subsequently, a mixed gas of silane (SiH₄) and ammonia (NH₃) is diluted with nitrogen (N₂), a reaction pressure is set to 50 Pa to 200 Pa, and constituent elements of the mixed gas break down into plasma by glow discharge in the chamber. Consequently, the antireflection layer 5 is formed on the substrate 1. The deposition temperature at this time is between about 350° C. and 650° C., and the temperature of the preheated substrate 1 is set higher than the deposition temperature by about 50° C. Frequencies from about 10 kHz to 500 kHz are used as frequencies of a high-frequency power supply needed for the glow discharge.

A flow of the mixed gas described above may be appropriately determined depending on the size of the chamber and the like, and may be in a range of 150 ml/min (seem) to 6000 ml/min (seem), for example. A flow ratio B/A between a flow A of silane and a flow B of ammonia may be 0.5 to 15.

Next, the third semiconductor layer 4 that contains the semiconductor impurities of the one conductivity type at a high concentration is formed on the second surface 1b side of the substrate 1. The third semiconductor layer 4 can be formed by, for example, thermal diffusion in which boron tribromide (BBr₃) is a source of diffusion of boron at a temperature between about 800° C. and 1100° C. Further, the third semiconductor layer 4 may be formed by applying a metal paste (also referred to as an aluminum paste) that contains aluminum powder, an organic vehicle and the like, for example, and contains aluminum as the main component by printing, and by subsequently heat treating (firing) the aluminum paste in a temperature range of about 600° C. to 850° C. to diffuse aluminum into the substrate 1.

Such techniques can form a region (also referred to as a diffusion region) in which the desired impurity elements are diffused only in the surface having the diffusion source of the impurity elements printed. Further, for example, the application of the above-mentioned technique for forming the second semiconductor layer 3 can eliminate the step of removing the reverse conductivity type layer of the n-type formed on the second surface 1b side of the substrate 1. In this case, after the desired diffusion region is formed as described above, the p-type semiconductor region and the n-type semiconductor region may be electrically separated by a technique such as irradiation with a laser beam in an outer peripheral portion of the first surface 1a or the second surface 1b of the substrate 1.

Next, the front electrode 6 and the back electrode 7 are formed as follows.

The front electrode 6 is formed by using the first metal paste. The first metal paste contains, for example, metal powder containing silver as the main component, an organic vehicle, and glass fits. Herein, first, the first metal paste is applied to the first surface 1a side of the substrate 1. Subsequently, the first metal paste is fired under the condition of a maximum temperature of 600° C. to 800° C. and a heating time of about a few tens of seconds to a few tens of minutes, to thereby form the front electrode 6. For example, screen printing or the like can be used as the technique for applying the first metal paste. After the application of the first metal paste, the solvent in the first metal paste may be evaporated at a predetermined temperature to dry the first metal paste. The front busbar electrode 6a and the front finger electrodes 6b of the front electrode 6 can be formed in one step by, for example, using screen printing.

The back busbar electrode 7a is formed by using the second metal paste. The second metal paste contains, for example, metal powder containing silver as the main component, an organic vehicle, glass frits and the like. For example, screen printing or the like can be used as the technique for applying the second metal paste. After the application of the second metal paste, the solvent may be evaporated at a predetermined temperature in the same manner as described above to dry the second metal paste. Subsequently, the substrate 1 on which the second metal paste is applied is fired by heating for about a few tens of seconds to a few tens of minutes on the condition that the maximum temperature is set between 600° C. and 850° C. in the firing furnace. Consequently, the back busbar electrode 7a is formed on the second surface 1b side of the substrate 1.

The back finger electrodes 7b are formed by using the third metal paste. The third metal paste contains, for example, metal powder containing aluminum as the main component, an organic vehicle, and glass frits. The third metal paste is applied to the second surface 1b side of the substrate 1 so as to contact part of the second metal paste that has been previously applied. The application may be performed on almost the entire surface on the second surface 1b side of the substrate 1 except for part of the portion in which the back busbar electrode 7a is to be formed. For example, screen printing or the like can be used as the technique for applying the third metal paste. After the application of the third metal paste, the solvent may be evaporated at a predetermined temperature in the same manner as described above to dry the third metal paste. Subsequently, the substrate 1 on which the third metal paste is applied is fired by heating for about a few tens of seconds to a few tens of minutes on the condition that the maximum temperature is set between 600° C. and 850° C. in the firing furnace. Consequently, the back finger electrodes 7b are formed on the second surface 1b side of the substrate 1. The third semiconductor layer 4 and the back finger electrodes 7b may be formed simultaneously by using the third metal paste.

First, the third metal paste is directly applied to the predetermined region of the passivation layer 9 to form the back finger electrodes 7b while the passivation layer 9 formed on the second surface 1b side of the substrate 1 remains. Then, a fire through technique in which heat treatment is performed at a maximum temperature set between 600° C. and 800° C. in the firing furnace may be used for the substrate 1. The fire through technique causes the components of the applied third metal paste to penetrate the passivation layer 9, to thereby form the third semiconductor layer 4 on the second surface 1b side of the substrate 1 and form the back finger electrodes 7b on the third semiconductor layer 4.

The solar cell element 10 can be manufactured in the steps described above.

In the steps described above, for example, the back finger electrodes 7b may be formed after the back busbar electrode 7a is formed. The back busbar electrode 7a does not necessarily directly contact the substrate 1. The passivation layer 9 may be located between the back busbar electrode 7a and the substrate 1.

The respective metal paste may be fired at the same time after the application of the respective metal paste to form the front electrode 6, the back busbar electrode 7a, and the back finger electrodes 7b. This increases productivity of the solar cell element 10 and reduces thermal history of the substrate 1 so that the output characteristics of the solar cell element 10 can be improved.

The back finger electrodes 7b may be formed substantially on the entire surface of the second surface 1b of the substrate 1 except for part of the region where the back busbar electrode 7a is formed. In this case, for example, the back finger electrodes 7b may be formed after an opening is formed in part of the passivation layer 9 by a technique such as irradiation with a laser beam and etching. Also, for example, a desired region of the third metal paste applied to the passivation layer 9 may be irradiated with a laser beam, to thereby form the back finger electrodes 7b that partially penetrate the passivation layer 9.

The disclosure is not limited to one embodiment described above and allows for the addition of many modifications and changes. For example, the substrate 1 may be cleaned before the passivation layer 9 is formed. Cleaning by hydrofluoric acid treatment, for example, can be used for cleaning the substrate 1. Cleaning by performing hydrofluoric acid treatment after performing the RCA clean (the cleaning technique developed by RCA in the United States and performed with mixed solution of sulfuric acid and hydrogen peroxide solution at high temperature and high concentration, dilute hydrofluoric acid (ambient temperature), mixed solution of ammonia water and hydrogen peroxide solution, mixed solution of hydrochloric acid and hydrogen peroxide solution, or the like) may also be used for cleaning the substrate 1. Cleaning by hydrofluoric acid treatment or the like after performing sulfuric acid/hydrogen peroxide/water mixture (SPM) cleaning can be used for cleaning the substrate 1.

Annealing with gas that contains hydrogen may be performed after the passivation layer 9 is formed. This can further reduce the speed of recombination of the minority carriers in the substrate 1.

For example, a double-sided light-receiving solar cell element in which light can be incident on both surfaces of the first surface 10a and the second surface 10b may be applied to the solar cell element 10.

For example, a substrate that predominantly includes the n-type semiconductor region is prepared, and the substrate having one surface in which the p-type semiconductor region is formed may be used as the semiconductor substrate.

<Solar Cell Module>

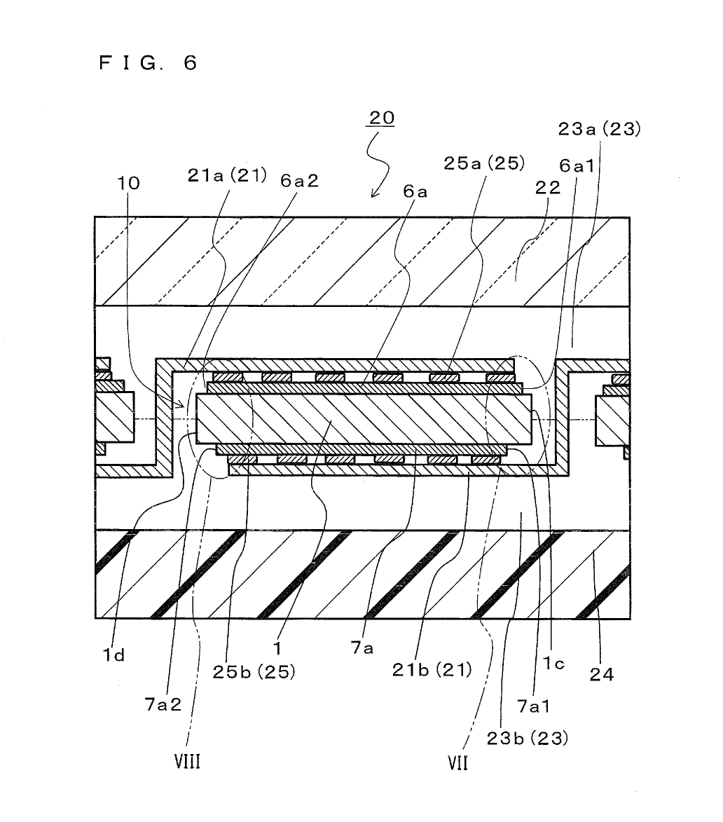

As illustrated in FIGS. 5 and 6, it is only required that the solar cell module 20 includes, for example, the plurality of solar cell elements 10 electrically connected to each other. The solar cell module 20 includes the plurality of solar cell elements 10 connected in, for example, series or parallel to each other, and electrical output can be taken out of the solar cell module 20.

The solar cell module 20 includes a laminated product of, for example, a transparent member 22, a filling material (specifically, a front filling material 23a and a back filling material 23b, for example), the connection tab 21 (specifically, a first connection tab 21a, a second connection tab 21b, and a third connection tab 21c, for example), the solder portions 25 (a first solder portion 25a and a second solder portion 25b, for example), the plurality of solar cell elements 10, and a back protective member 24.

Herein, the transparent member 22 is a member for protecting the light-receiving surface of the solar cell module 20. A flat member having transparency such as a glass substrate may be used as the transparent member 22.

Both of the front filling material 23a and the back filling material 23b are a transparent filling material such as ethylene-vinyl acetate (EVA) and polyolefin resin.

The back protective member 24 is a member for protecting the back surface of the solar cell module 20. For example, polyethylene terephthalate (PET) or polyvinyl fluoride (PVF) resin is applied as a material for the back protective member 24. The back protective member 24 may have a single-layer structure or a laminated structure. The whole back protective member 24 may be colored in white or black.

The connection tab 21 is a member (also referred to as a connection member) for electrically connecting the plurality of solar cell elements 10 to each other. In the plurality of solar cell elements 10 included in the solar cell module 20, for example, the front busbar electrode 6a of one of the solar cell elements 10 adjacent to each other in one direction is electrically connected to the back busbar electrode 7a of the other of the solar cell elements 10 with the connection tab 21 through the solder portions 25. Specifically, for example, the front busbar electrode 6a is connected to the first connection tab 21a through the first solder portion 25a. The back busbar electrode 7a is connected to the second connection tab 21b through the second solder portion 25b. One end portion of the first connection tab 21a is located on the first lateral surface 1c side of the substrate 1 and the first connection tab 21a is located on the front busbar electrode 6a along the front busbar electrode 6a. The first solder portion 25a is located between the front busbar electrode 6a and the first connection tab 21a and connects the front busbar electrode 6a and the first connection tab 21a to each other. One end portion of the second connection tab 21b is located on the second lateral surface 1d side of the substrate 1 and the second connection tab 21b is located on the back busbar electrode 7a along the back busbar electrode 7a. The second solder portion 25b is located between the back busbar electrode 7a and the second connection tab 21b and connects the back busbar electrode 7a and the second connection tab 21b to each other.

As illustrated in FIG. 5, the solar cell module 20 includes, for example, a first solar cell string S1 that includes the plurality of solar cell elements 10 connected in series and a second solar cell string S2 adjacent to the first solar cell string S1. One end portion of the first solar cell string S1 and one end portion of the second solar cell string S2 are electrically connected to each other with the third connection tab 21c having a different shape from the shapes of the first connection tab 21a and the second connection tab 21b through the solder portions 25.

Herein, a copper foil, for example, can be used as the connection tab 21 (specifically, the first connection tab 21a, the second connection tab 21b, and the third connection tab 21c, for example), and, furthermore, the copper foil coated with solder can also be used as the connection tab 21. The connection tab 21 may have a thickness of, for example, about 0.1 mm to 0.2 mm. The connection tab 21 may have a width of, for example, about 1 mm to 3 mm.

Of the plurality of solar cell elements 10 electrically connected in series, one end of an electrode of a first solar cell element 10 and one end of an electrode of a last solar cell element 10 are each electrically connected to a terminal box serving as an output extraction portion with an output extraction line. The solar cell module 20 may include a frame body 26 that is located around the above-mentioned laminated product and holds the laminated product. For example, aluminum having corrosion resistance and strength is applied as a material for the frame body 26.

As illustrated in FIGS. 6 to 8, both ends (a first tip 6a1 and a second tip 6a2) in the longitudinal direction of the front busbar electrode 6a are located closer to the outside than both ends in the longitudinal direction of the first solder portion 25a on the first lateral surface 1c side and the second lateral surface 1d side of the substrate 1 in the solar cell module 20. Both ends (a first tip 7a1 and a second tip 7a2) in the longitudinal direction of the back busbar electrode 7a are located closer to the outside than both ends in the longitudinal direction of the second solder portion 25b. Further, both ends (a first tip R1a and a second tip R1b) in a longitudinal direction of a first bonding surface R1 where the first solder portion 25a is bonded (adhering) to the front busbar electrode 6a are located closer to the outside than both ends (a first tip R2a and a second tip R2b) in a longitudinal direction of a second bonding surface R2 where the second solder portion 25b is bonded (adhering) to the back busbar electrode 7a on the first lateral surface 1c side and the second lateral surface 1d side of the substrate 1.

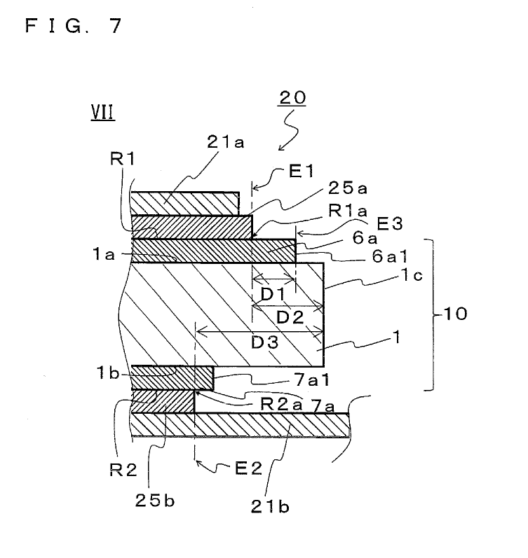

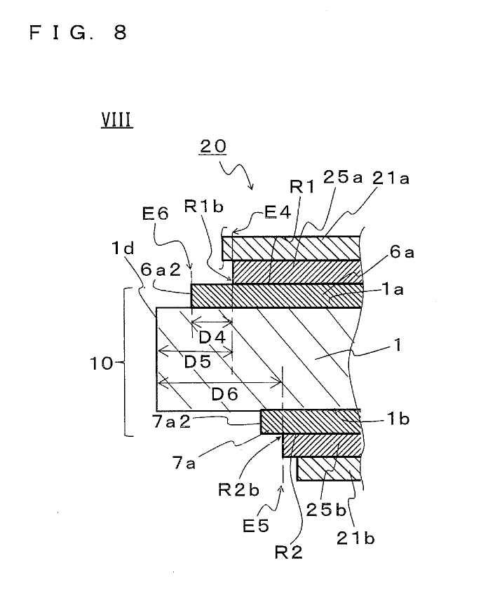

As illustrated in FIG. 7, the first tip R1a of the first bonding surface R1 is located closer to the outside (namely, to the first lateral surface 1c side) than the first tip R2a of the second bonding surface R2 in a portion of the solar cell element 10 on the first lateral surface 1c side. Further, as illustrated in FIG. 8, the second tip R1b of the first bonding surface R1 is located closer to the outside (namely, to the second lateral surface 1d side) than the second tip R2b of the second bonding surface R2 in a portion of the solar cell element 10 on the second lateral surface 1d side. That is to say, as illustrated in FIGS. 7 and 8, in the longitudinal direction of the front busbar electrode 6a and the back busbar electrode 7a, a shortest distance (D2) between the first lateral surface 1c of the substrate 1 and the first bonding surface R1 is shorter than a shortest distance (D3) between the first lateral surface 1c and the second bonding surface R2 while a shortest distance (D5) between the second lateral surface 1d and the first bonding surface R1 is shorter than a shortest distance (D6) between the second lateral surface 1d and the second bonding surface R2. As illustrated in FIGS. 7 and 8, in the longitudinal direction of the front busbar electrode 6a and the back busbar electrode 7a, a shortest distance (difference between D2 and D1) between the first lateral surface 1c of the substrate 1 and the front busbar electrode 6a is shorter than the shortest distance (D2) between the first lateral surface 1c and the first bonding surface R1 while a shortest distance (difference between D5 and D4) between the second lateral surface 1d and the front busbar electrode 6a is shorter than the shortest distance (D5) between the second lateral surface 1d and the first bonding surface R1.

The “both ends (tips) in the longitudinal direction” of the front busbar electrode 6a and the back busbar electrode 7a as well as the first bonding surface R1 and the second bonding surface R2 refer to portions located closest to the lateral surfaces of the substrate 1 in the plan view.

A difference in thermal expansion coefficient between the connection tab 21 of heated metal and the substrate 1 of heated semiconductor at the time of soldering causes the connection tab 21 to contract greater than the substrate 1 during cooling, thereby generating residual stress in the surface of the substrate 1. It is conceivable that a crack starting from a location in which tensile stress higher than a predetermined level is generated is likely to occur in the substrate 1. For the width of the connection tab 21, the first connection tab 21a connected to the front busbar electrode 6a and the second connection tab 21b connected to the back busbar electrode 7a each have the same constant width. Accordingly, the tensile stress is likely to increase particularly at the both ends (the first tip R1a and the second tip R1b) of the first bonding surface R1 due to a difference in pattern (width, dimensions) among the front busbar electrode 6a, the back busbar electrode 7a, and the solder portions 25. Thus, the crack starting from the first bonding surface R1 is likely to occur. The reason is that the front busbar electrode 6a has an area and/or a width set to be smaller than those of the back busbar electrode 7a in the plan view to reduce an influence of light shielding by the front electrode 6.

Thus, the both ends (the first tip 6a1 and the second tip 6a2) of the front busbar electrode 6a are located closer to the outside (the first lateral surface 1c side and the second lateral surface 1d side of the substrate 1) than the both ends (the first tip R1a and the second tip R1b) of the first bonding surface R1 in one embodiment. This makes unnecessary tensile stress less likely to be applied to the both end portions of the front busbar electrode 6a in the solar cell module 20 in one embodiment. The occurrence of the crack in the substrate 1 in the vicinity of the both ends of the front busbar electrode 6a can thus be reduced.

If, herein, even one end of the second bonding surface R2 is located closer to the outside than one end of the first bonding surface R1 on the back busbar electrode 7a side, the tensile stress in the first surface 10a on the end portion side increases, so that the crack is more likely to occur in the substrate 1. The both ends of the front busbar electrode 6a are located closer to the outside than the both ends of the first solder portion 25a while the both ends of the back busbar electrode 7a are located closer to the outside than the both ends of the second solder portion 25b. This relieves the concentration of the stress in the first surface 10a in which the crack is likely to occur, so that the occurrence of the crack in the substrate 1 can be reduced.

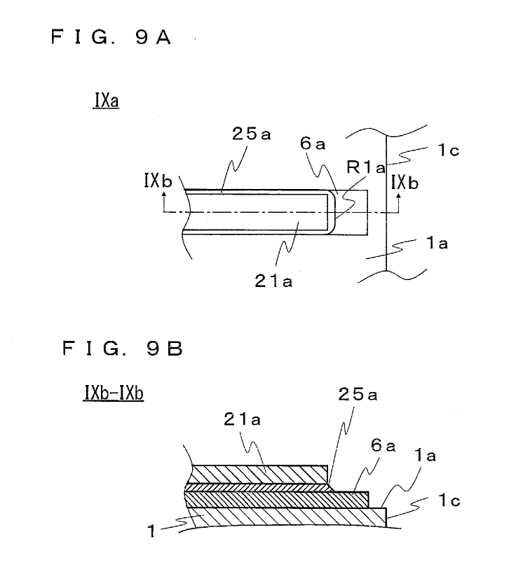

As illustrated in FIG. 4B, for example, an electrode having a pattern that includes a frame-shaped portion having long cavities (slits) in the width direction of the front busbar electrode 6a may be applied to the front busbar electrode 6a. For example, the front busbar electrode 6a may have a portion having slits and a portion having no slit, assuming that the end portion of the front busbar electrode 6a is the region having no slit. In this case, for example, as illustrated in FIGS. 9A and 9B, the region having no slit may be located in the front busbar electrode 6a at the portions of the tips (the first tip R1a and the second tip R1b) in the longitudinal direction of the first bonding surface R1. If, herein, the solder portions 25 are formed on the region having the slits of the front busbar electrode 6a, the residual stress is increased by an influence of thermal stress during formation of the electrode and soldering of the connection tab 21. However, for example, if the front busbar electrode 6a has no slit at the both ends of the first bonding surface R1, unnecessary tensile stress is less likely to be applied to the front busbar electrode 6a. Thus, the crack is less likely to occur in the substrate 1 at the portion of the first bonding surface R1. When the region of the front busbar electrode 6a except for the both end portions has the slits, the amount of the material used for the front busbar electrode 6a can be reduced. This can increase productivity of the solar cell elements 10 and the solar cell module 20.

Particularly in a case in which the front busbar electrode 6a is formed by screen printing, for example, the front busbar electrode 6a can have a shape having the slits, as illustrated in FIGS. 4A and 4B. In this case, an adequate gap can be easily maintained between the screen used in screen printing and the solar cell elements 10 in comparison with the case in which the front busbar electrode 6a has the pattern having no slit as illustrated in FIG. 1. Thus, the front busbar electrode 6a can easily maintain an adequate thickness. Consequently, the front busbar electrode 6a having excellent electrical and mechanical characteristics may be formed.

The solder portions 25 may be continuously located in the longitudinal direction of the connection tab 21. As illustrated in FIG. 4C, the front busbar electrode 6a and the back busbar electrode 7a may have the pattern such that the front busbar electrode 6a and the back busbar electrode 7a divided into the plurality of island-shaped portions are located. Thus, the shape and the size of the solder portions 25 are easily appropriately set. As a result, the thermal stress caused by soldering of the connection tab 21 in the whole solar cell module 20 may be reduced. Moreover, for example, the front finger electrodes 6b can be disposed in the space between the island-shaped portions of the front busbar electrodes 6a, and the back finger electrodes 7b and the third semiconductor layer (also referred to as a BSF layer) 4 can be disposed in the space between the island-shaped portions of the back busbar electrodes 7a. The improved photoelectric conversion efficiency of the solar cell elements 10 can thus be expected. For example, when the front busbar electrode 6a and the back busbar electrode 7a are each formed by being divided into the plurality of island shapes, the regions of the solder portions 25 are easily set. In this case, for example, the amount of the materials used for forming the front busbar electrode 6a and the back busbar electrode 7a can be further reduced. As a result, productivity of the solar cell elements 10 and the solar cell module 20 can be increased.

As illustrated in FIG. 9A, the both ends of the first bonding surface R1 and the second bonding surface R2 may have a curved shape such as an arc shape and a wave shape instead of a linear shape in the plan view. In this case, a distance between the both ends of each of the first bonding surface R1 and the second bonding surface R2 is increased in comparison with the case in which the both ends of the first bonding surface R1 and the second bonding surface R2 have the linear shape. Thus, the stress generated during soldering of the connection tab 21 at the both ends of the first bonding surface R1 and the second bonding surface R2 may be reduced.

For example, as illustrated in FIG. 4D, the front busbar electrode 6a and the back busbar electrode 7a may each have a width at the both end portions in the longitudinal direction larger than a width of a remaining portion other than the both end portions. In this case, for example, the stress generated during soldering of the connection tab 21 in the first bonding surface R1 or the second bonding surface R2 may be reduced.

A temperature in soldering of the connection tab 21 tends to be higher when the non-lead solder, which is environmentally friendly, is used as the solder used for soldering of the connection tab 21 than when a lead solder is used. Thus, the crack is more likely to occur in the substrate 1 in some cases. Even in this case, the application of the structure in one embodiment can reduce the occurrence of the crack in the substrate 1.

<Method for Manufacturing Solar Cell Module>

With reference to FIGS. 5 and 6, a specific method for manufacturing the solar cell module 20 is described in detail. First, the plurality of solar cell elements 10 are arranged in series and/or parallel, and adjacent solar cell elements 10 are electrically connected to each other with the connection tab 21. A technique using a soldering iron, hot air, a laser beam, or pulse heating can be applied to the technique for connecting the solar cell elements 10 to each other with the connection tab 21. With such a technique, the connection tab 21 is soldered to each of the front busbar electrode 6a and the back busbar electrode 7a. At this time, a position in which the connection tab 21 is heated is adjusted so as to adjust a position in which the front busbar electrode 6a and the first connection tab 21a are connected to each other with the first solder portion 25a. Similarly, a position in which the back busbar electrode 7a and the second connection tab 21b are connected to each other with the second solder portion 25b can also be adjusted.

Next, the front filling material 23a is placed on the transparent member 22, and the plurality of solar cell elements 10 to which the connection tab 21 and the output extraction line are connected are placed on the front filling material 23a. Further, the back filling material 23b and the back protective member 24 are laminated in the sequential order on the plurality of solar cell elements 10. Subsequently, the output extraction line is led from a slit (not shown) located in each member on the back surface side to the outside of the back protective member 24 to obtain the laminated product. The laminated product is then set in a laminator. While being pressurized under a reduced pressure in the laminator, the laminated product is heated at temperatures between about 80° C. and 200° C. for, for example, 15 minutes to 60 minutes. Consequently, the solar cell module 20 that includes the integrated laminated product can be obtained.

Next, mounting of a terminal box (not shown) is performed. Specifically, the terminal box is mounted on the back protective material 24 from which the output extraction line is led with an adhesive such as silicone resin. The output extraction lines on the plus side and the minus side are fixed to terminals (not shown) of the terminal box by soldering, for example. A lid is then mounted on the terminal box.

Finally, mounting of the frame body 26 is performed to complete the solar cell module 20. Specifically, the frame body 26 made of, for example, aluminum is mounted on the outer peripheral portion of the solar cell module 20. The mounting of the frame body 26 can be performed by, for example, fixing the corner portions of the frame body 26 with screws. In this manner, the solar cell module 20 is completed.

### EXAMPLES

An example will be described below. Positions of a front busbar electrode 6a, a back busbar electrode 7a, a first bonding surface R1, and a second bonding surface R2 in each solar cell module including 48 solar cell elements connected to each other were modified to manufacture four solar cell modules for each of Condition 1 to Condition 7 and Condition 9, and to manufacture one solar cell module for each of Condition 8 and Condition 10 shown in Table 1. Electrode patterns of the front busbar electrode 6a and the back busbar electrode 7a were the belt-shaped pattern illustrated in FIGS. 1 and 2 and the respective patterns illustrated in FIGS. 4A to 4D. For the pattern of FIG. 4A, the size of the slit was 1 mm×0.2 mm and the distance between the adjacent slits was 1 mm. For the patterns of FIGS. 4B and 4D, the end portion having no slit had the length of 8 mm. For the pattern of FIG. 4C, the distance L1 between the adjacent island-shaped portions was 8 mm and each of the island-shaped portions had the length of 8 mm.

First, a polycrystalline substrate 1 having a square shape with one side of about 156 mm in the plan view and having a thickness of about 200 μm was prepared as the semiconductor substrate 1 including a first semiconductor layer 2 of a p-type. Etching was performed on the surface of the substrate 1 with an aqueous solution of NaOH to remove a damage layer of the surface, and then cleaning was performed. Processing below was performed on the substrate 1 prepared as described above.

A texture was formed on the first surface 1a side of the substrate 1 by RIE.

Next, phosphorus was diffused into the substrate 1 by a vapor thermal diffusion in which POCl₃ was a source of diffusion of phosphorus to form a second semiconductor region 3 of an n-type having a sheet resistance of about 90 Ω/□. After the second semiconductor layer 3 formed on the lateral surfaces of the substrate 1 and the second surface 1b side of the substrate 1 was removed with a hydrofluoric-nitric acid solution, the phosphorus glass remaining on the substrate 1 was removed with a hydrofluoric acid solution.

Next, an aluminum oxide layer was formed as a passivation layer 9 on the entire surface of the substrate 1 by ALD. Subsequently, an antireflection layer 5, which was a silicon nitride film, was formed on the passivation layer 9 on the first surface 1a side of the substrate 1 by PECVD.

Next, a first metal paste (also referred to as a silver paste) that contained silver as the main component was applied into a pattern of a front electrode 6 to the first surface 1a side of the substrate 1, and a second metal paste (also referred to as a silver paste) that contained silver as the main component was applied into a pattern of the back busbar electrode 7a to the second surface 1b side of the substrate 1. Subsequently, a third metal paste (also referred to as an aluminum paste) that contained aluminum as the main component was applied into patterns of the back finger electrodes 7b to the second surface 1b side of the substrate 1. The pastes were fired to form a third semiconductor layer 4, the front electrode 6, and a back electrode 7 to manufacture a solar cell element 10.

Next, a connection tab 21 was adhering to each of the front busbar electrode 6a and the back busbar electrode 7a with a eutectic solder. The connection tab 21 was manufactured by immersing a copper foil having a thickness of about 200 μm in a melted solder reservoir to form a solder layer having a thickness of about 20 μm around the copper foil. The connection tab 21 was disposed on each of the front busbar electrode 6a and the back busbar electrode 7a of the solar cell element 10.

Next, hot air at a temperature between about 400° C. and 500° C. was applied to the connection tab 21 for about a second to two seconds while the connection tab 21 was pressed against the front busbar electrode 6a and the back busbar electrode 7a. The application of the hot air was then stopped, and the solar cell element 10 cooled to ambient temperature to fixedly attach the connection tab 21 to the front busbar electrode 6a and the back busbar electrode 7a. At this time, the positions of the first bonding surface R1 and the second bonding surface R2 respectively on the first surface 1a side and the second surface 1b side of the substrate 1 were modified as indicated by Condition 1 to Condition 10 in Table 1.

The solar cell element 10 to which the connection tab 21 was fixedly attached cooled to ambient temperature. In this manner, the solar cell modules each including the 48 solar cell elements connected to each other were manufactured in groups of five. Subsequently, in each of the solar cell modules, a fluorescent flaw detection solution was applied to the second surface 1b side of the substrate 1 (namely, the second surface 10b side of the solar cell element 10), and light of black light was applied from the first surface 1a side (namely, the first surface 10a side of the solar cell element 10) to the solar cell element 10, to thereby visually check an occurrence of a crack in the substrate 1. Table 1 shows the results.

TABLE 1

| | D1 | D2 | D3 | D4 | D5 | D6 | W1 | W2 | W3 | OCCURRENCE |
|---|---|---|---|---|---|---|---|---|---|---|
| | (mm) | (mm) | (mm) | (mm) | (mm) | (mm) | (mm) | (mm) | (mm) | OF CRACK |
| CONDITION 1 | 0.0 | 10 | 10 | 0.0 | 10 | 10 | 1.6 | 1.6 | 1.5 | X(Not Good) |
| CONDITION 2 | 0.1 | 10 | 10 | 0.1 | 10 | 10 | 1.6 | 1.6 | 1.5 | Δ(Good) |
| CONDITION 3 | 1.0 | 10 | 10 | 1.0 | 10 | 10 | 1.6 | 1.6 | 1.5 | Δ(Good) |
| CONDITION 4 | 0.0 | 8 | 10 | 0.0 | 8 | 10 | 1.6 | 1.6 | 1.5 | ◯(Very Good) |
| CONDITION 5 | 0.1 | 8 | 10 | 0.1 | 8 | 10 | 1.6 | 1.6 | 1.5 | ⊚(Excellent) |
| CONDITION 6 | 0.1 | 10 | 8 | 0.1 | 10 | 8 | 1.6 | 1.6 | 1.5 | X(Not Good) |
| CONDITION 7 | 0.0 | 10 | 10 | 0.0 | 10 | 10 | 1.6 | 1.6 | 1.3 | Δ(Good) |
| CONDITION 8 | 0.0 | 10 | 10 | 0.0 | 10 | 10 | 1.6 | 1.8 | 1.5 | Δ(Good) |
| CONDITION 9 | 0.1 | 8 | 10 | 0.1 | 8 | 10 | 1.6 | 1.6 | 1.3 | ⊚(Excellent) |
| CONDITION 10 | 0.1 | 8 | 10 | 0.1 | 8 | 10 | 1.6 | 1.8 | 1.5 | ⊚(Excellent) |

Herein, as illustrated in FIG. 7, D1 in Table 1 represents a distance from a tip position E1 of the first solder portion 25a to a tip position E3 of the front busbar electrode 6a in the longitudinal direction of the front busbar electrode 6a on the first lateral surface 1e side of the substrate 1. As illustrated in FIG. 7, D2 in Table 1 represents a distance from the tip position E1 of the first solder portion 25a to the first lateral surface 1c of the substrate 1 in the longitudinal direction of the front busbar electrode 6a on the first lateral surface 1c side of the substrate 1. As illustrated in FIG. 7, D3 in Table 1 represents a distance from a tip position E2 of the second solder portion 25b to the first lateral surface 1c of the substrate 1 in the longitudinal direction of the back busbar electrode 7a on the first lateral surface 1c side of the substrate 1. As illustrated in FIG. 8, D4 in Table 1 represents a distance from a tip position E4 of the first solder portion 25a to a tip position E6 of the front busbar electrode 6a in the longitudinal direction of the front busbar electrode 6a on the second lateral surface id side of the substrate 1. As illustrated in FIG. 8, D5 in Table 1 represents a distance from the tip position E4 of the first solder portion 25a to the second lateral surface 1d of the substrate 1 in the longitudinal direction of the front busbar electrode 6a on the second lateral surface 1d side of the substrate 1. As illustrated in FIG. 8, D6 in Table 1 represents a distance from a tip position E5 of the second solder portion 25b to the second lateral surface 1d of the substrate 1 in the longitudinal direction of the back busbar electrode 7a on the second lateral surface 1d side of the substrate 1.

As illustrated in FIGS. 4A to 4D, for example, W1 in Table 1 represents a width of a portion, except for an end portion, of the front busbar electrode 6a to which the first connection tab 21a was bonded through the first solder portion 25a. As illustrated in FIG. 4D, for example, W2 in Table 1 represents a width of the end portion of the front busbar electrode 6a to which the first connection tab 21a was bonded through the first solder portion 25a. W3 in Table 1 represents a width of the connection tab 21.

In Table 1, Condition 4, Condition 5, Condition 9, and Condition 10 show the conditions of the solar cell module according to the example of the disclosure, and Condition 1 to Condition 3 and Condition 6 to Condition 8 show the conditions of the solar cell module according to a reference example.

It was determined that among Condition 1 to Condition 10 in Table 1, the conditions were “\textcircled{∘} (Excellent)” if the occurrence of the crack was not recognized at all in the solar cell elements forming the solar cell module. On the other hand, it was determined that the conditions were “∘ (Very Good)” if the solar cell elements in which the occurrence of even one crack was recognized accounted for greater than 0% and less than 5% of the solar cell module. It was determined that the conditions were “Δ (Good)” if the solar cell elements in which the occurrence of even one crack was recognized accounted for greater than or equal to 5% and less than 10% of the solar cell module. It was determined that the conditions were “x (Not Good)” if the solar cell elements in which the occurrence of even one crack was recognized accounted for greater than or equal to 10% of the solar cell module.

As seen from Table 1, the solar cell elements in which the crack occurred accounted for less than 5% of the solar cell module in Condition 4 while the occurrence of the crack was not recognized at all in the solar cell elements of the solar cell modules in Condition 5, Condition 9, and Condition 10. It turned out that the respective electrode patterns of the front busbar electrode 6a in the order of FIG. 4C, FIG. 4B, and FIG. 4A could reduce the occurrence of the crack in the solar cell module in Condition 4.

As described above, it was recognized that the occurrence of the crack in the solar cell elements was reduced in the solar cell modules in Condition 4, Condition 5, Condition 9, and Condition 10 in comparison with the solar cell modules in Condition 1 to Condition 3 and Condition 6 to Condition 8.

1. A solar cell module, comprising:
a solar cell element that includes a semiconductor substrate having a first lateral surface and a second lateral surface located opposite to the first lateral surface, a front busbar electrode located on a first surface side of the semiconductor substrate along a direction from the first lateral surface toward the second lateral surface, and a back busbar electrode located on a second surface side opposite to the first surface side of the semiconductor substrate along the direction from the first lateral surface toward the second lateral surface so as to be located at a position opposite to the front busbar electrode with the substrate interposed therebetween;
a first connection tab that is located just above the front busbar electrode along a longitudinal direction of the front busbar electrode and includes one end portion located on the first lateral surface side of the semiconductor substrate;
a first solder portion that is located between the front busbar electrode and the first connection tab and connects the front busbar electrode and the first connection tab to each other;
a second connection tab that is located just above the back busbar electrode along a longitudinal direction of the back busbar electrode and includes one end portion located on the second lateral surface side of the semiconductor substrate; and
a second solder portion that is located between the back busbar electrode and the second connection tab and connects the back busbar electrode and the second connection tab to each other,
wherein a shortest distance between the first lateral surface and a first bonding surface where the first solder portion is bonded to the front busbar electrode is shorter than a shortest distance between the first lateral surface and a second bonding surface where the second solder portion is bonded to the back busbar electrode while a shortest distance between the second lateral surface and the first bonding surface is shorter than a shortest distance between the second lateral surface and the second bonding surface.

2. The solar cell module according to claim 1, wherein in the longitudinal direction of the front busbar electrode, a shortest distance between the first lateral surface and the front busbar electrode is shorter than the shortest distance between the first lateral surface and the first bonding surface while a shortest distance between the second lateral surface and the front busbar electrode is shorter than the shortest distance between the second lateral surface and the first bonding surface.

3. The solar cell module according to claim 1, wherein the front busbar electrode includes a frame-shaped portion.

4. The solar cell module according to claim 1, wherein
the front busbar electrode includes both end portions in the longitudinal direction of the front busbar electrode and a remaining portion other than the both end portions, and
at least one end portion of the both end portions has a width larger than a width of the remaining portion.

5. The solar cell module according to claim 1, wherein the front busbar electrode includes a plurality of island-shaped portions that are discontinuous portions.

6. The solar cell module according to claim 1, wherein the first solder portion and the second solder portion contain a non-lead solder.
